(19) United States
(12) Patent Application Publication
(10) Pub. No.: US 2026/0173562 A1
(43) Pub. Date: Jun. 18, 2026

(54) PIXEL STRUCTURE AND METHOD OF FORMING THE SAME

(71) Applicant: OMNIVISION TECHNOLOGIES, INC., Santa Clara, CA (US)

(72) Inventor: Shin Iwabuchi, Fujisawa (JP)

(73) Assignee: OMNIVISION TECHNOLOGIES, INC., Santa Clara, CA (US)

(21) Appl. No.: 18/984,929

(22) Filed: Dec. 17, 2024

(51) Int. Cl. H10F 39/00; H10F 39/18

(52) U.S. Cl. CPC H10F 39/807; H10F 39/014; H10F 39/028; H10F 39/182

(57) ABSTRACT

A pixel structure and a method of forming the same are provided. The pixel structure includes a semiconductor substrate, a trench isolation, a semiconductor layer and a doped region. The trench isolation is disposed in the semiconductor substrate. The semiconductor layer is disposed in the semiconductor substrate and surrounded by the trench isolation. The semiconductor layer has a first conductive type and a photodiode is formed in the semiconductor layer. The doped region is disposed between the trench isolation and the semiconductor layer and has a second conductive type opposite to the first conductive type. The doped region extends between a first surface and a second surface opposite to the first surface of the semiconductor substrate, and a width of the doped region decreases as the doped region becomes closer to the first surface. The pixel structure may optimize full well capacity and charge transfer efficiency.

### BACKGROUND

### Technical Field

The present disclosure relates to a pixel structure of an image sensor and a method of forming the same.

### Description of Related Art

To address a request to increase the resolution of an image sensor mounted on a mobile apparatus, photodiode area may be reduced to increase pixels in number.

A back-illuminated photodiode has to transfer electric charge resulting from photoelectric conversion proximate to the rear surface side (e.g., illuminated side) to the front surface side (e.g., non-illuminated side) in the photodiode to cause a transistor formed on the front surface side to read out the electric charge. A method has been therefore known that facilitates the movement of generated electric charge by causing the impurity concentration (e.g., n-type impurities) of the photodiode in the depth direction to have a gradient.

However, in order to form a photodiode with a gradient impurity concentration from the front surface side to the rear surface side it is necessary to perform impurity doping process many times with different dosages and at different impanation energy. The doped region also extends in the transverse direction under conditions of deep doping proximate to the rear surface side. This raises an issue on processing difficulty in causing a photodiode having a small area to have a concentration gradient optimal for the movement of electric charge(s). In addition, there is also an issue about the increased lead time and the reduced throughput due to the prolonged time of the doping process.

### SUMMARY

In some embodiments, an image sensor includes a pixel array with a pixel structure providing full deep trench isolation between adjacent pixel/pixel cells within a semiconductor material (e.g., semiconductor substrate, wafer, epitaxial layer).

In some embodiments of present disclosure, a pixel structure includes a semiconductor substrate, a trench isolation, a semiconductor layer and a doped region. The semiconductor substrate has a first surface and a second surface opposite to the first surface. The trench isolation is disposed in the semiconductor substrate. The semiconductor layer is disposed in the semiconductor substrate and surrounded by the trench isolation, wherein the semiconductor layer has a first conductive type and a photodiode is formed in the semiconductor layer. The doped region is disposed between the trench isolation and the semiconductor layer, the doped region has a second conductive type opposite to the first conductive type, wherein the doped region extends between the first surface and the second surface, and a width of the doped region decreases as the doped region becomes closer to the first surface.

In an embodiment, the doped region includes a first portion and a second portion. The first portion of the doped region is arranged to extend from the first surface to a first depth with respect to the first surface along a first direction, and the first portion has a first width in a second direction substantially perpendicular to the first direction. The second portion of the doped region is disposed between the first portion and the second surface, the second portion has a second width in the second direction, wherein the first width is less than the second width.

In an embodiment, the first portion has the first width which is substantially constant from the first surface to the first depth, and the second portion has the second width which is substantially constant from the first depth to the second surface.

In an embodiment, the semiconductor layer includes a first region and a second region. The first region of the semiconductor layer is surrounded by the first portion of the doped region and the first region of the semiconductor layer has a first region impurity concentration of the first conductive type. The second region of the semiconductor layer is surrounded by the second portion of the doped region and the second region of the semiconductor layer has a second region impurity concentration of the first conductive type, wherein the second region impurity concentration of the second region is lower than the first region impurity concentration of the first region.

In an embodiment, the first portion of the doped region has a first impurity concentration of the second conductive type, the second portion of the doped region has a second impurity concentration of the second conductive type, and the first impurity concentration of the first portion is smaller than the second impurity concentration of the second portion.

In some embodiments, the second portion of the doped region is in direct contact with the first portion of the doped region. The second portion may vertically extend from the first portion of the doped region toward the second surface of the semiconductor layer. In same or different embodiments, the second portion of the semiconductor layer is in direct contact with the first portion of the semiconductor layer.

In an embodiment, the doped region further includes at least one third portion between the first portion of the doped region and the second portion of the doped region. The at least one third portion of the doped region has a third width in the second direction, wherein the third width may range between the first width and the second width.

In the same or different embodiments, the first portion of the doped region has a first impurity concentration of the second conductive type, the second portion of the doped region has a second impurity concentration of the second conductive type, the third portion of the doped region has a third impurity concentration of the second conductive type, and each of the first impurity concentration, the second impurity concentration and the third impurity concentration is larger than an impurity concentration of the second conductive type of the semiconductor layer.

In an embodiment, the first impurity concentration is smaller than the second impurity concentration, and the third impurity concentration is between the first impurity concentration and the second impurity concentration.

In an embodiment, the semiconductor layer further includes at least one third region between the first region of the semiconductor layer and the second region of the semiconductor layer, the at least one third region portion of the semiconductor layer has a third region width in the second direction and between a first region width of the first region of the semiconductor layer and the second region width of the second region of the semiconductor layer.

In an embodiment, the doped region has a width turning point at a first depth in the semiconductor layer.

In an embodiment, the semiconductor layer has a step boundary interfacing the doped region.

In an embodiment, surfaces of the doped region, the trench isolation and the semiconductor layer are substantially coplanar.

In an embodiment, the doped region is in direct contact with the trench isolation and the semiconductor layer.

In an embodiment, the pixel structure further includes a transfer gate and a floating diffusion region. The transfer gate is disposed proximate to the first surface of the semiconductor layer. The floating diffusion region is disposed in the semiconductor substrate and adjacent to the first surface, wherein the transfer gate couples the photodiode to the floating diffusion region.

In an embodiment, the doped region has a vertical thickness being the same as a trench depth of the trench isolation with respect to the first surface.

In some embodiments of present disclosure, a method of forming a pixel structure includes the following steps. A trench and a semiconductor layer of a first conductive type are formed in a semiconductor substrate, wherein the semiconductor layer is surrounded by the trench. A doped region is formed in the semiconductor layer adjacent to the trench, wherein the doped region is of a second conductive type opposite to the first conductive type and arranged to extend from a first depth to the second surface. First impurities of the second conductive type are diffused into the semiconductor layer between the doped region and the first surface and into the doped region, to form a first doped region between the first surface and the first depth and a second doped region between the first depth and the second surface. A trench isolation is formed in the trench.

In an embodiment, forming the doped region in the semiconductor layer includes the following steps. A stopper layer is formed adjacent to a first trench portion of the trench lining sidewalls of the first trench between the first surface and the first depth while a second trench portion of the trench between the first depth and the second surface is free of the stopper layer. Second impurities of the second conductive type are diffused into the semiconductor layer through the second trench portion of the trench.

In an embodiment, diffusing the second impurities of the second conductive type into the semiconductor layer includes the following steps. The second impurities of the second conductive type are formed adjacent to the second trench portion of the trench by a plasma doping process. The second impurities of the second conductive type are diffused into the semiconductor layer by an annealing process.

In an embodiment, diffusing the second impurities of the second conductive type into the semiconductor layer includes the following steps. A layer including the second impurities of the second conductive type is formed adjacent to the first trench portion and the second trench portion of the trench. The second impurities of the second conductive type are diffused into the semiconductor layer by an annealing process.

According to some embodiments of the present disclosure, the formation of the doped region that changes in widths allows the semiconductor layer to have an impurity concentration gradient. In one embodiment, the doped region is of p-type (also referred to as p-type doped region) and the semiconductor layer is of n-type (also referred to as n-type semiconductor layer). In such embodiment, the p-type doped region is configured with varying thickness along the depthwise direction, which enables the n-type semiconductor layer to have concentration gradient. The n-typed semiconductor layer surrounded by the p-type doped region may be configured to have a potential gradient from the second surface (e.g., backside surface) to the first surface (e.g., front surface) in a unit pixel. It is thus possible to facilitate electric charges (e.g., electrons) accumulated from photoelectric conversion in the photodiode in response to an incident light to move from the second surface (e.g., backside surface) to the first surface (e.g., front surface).

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1A is a cross-sectional view of a pixel structure according to some embodiments of the present disclosure, FIG. 1B illustrates the first conductive type impurity concentration and the potentials of the semiconductor layer of the pixel of FIG. 1A in the second direction at different regions along the first direction from the first surface to the second surface according to some embodiments of the present disclosure, and FIG. 1C illustrates the potentials of the semiconductor layer 14 in the second direction near the middle of the pixel of FIG. 1A in the first direction from the first surface to the second surface according to some embodiments of the present disclosure.

FIG. 2A to FIG. 2J illustrate cross-sectional views of a method of forming a pixel structure.

FIG. 3 is a cross-sectional sectional view of a pixel structure according to some embodiments of the present disclosure.

FIG. 4 is a cross-sectional sectional view of a pixel structure according to some embodiments of the present disclosure.

FIG. 5 is a cross-sectional sectional view of an image sensor according to some embodiments of the present disclosure.

Corresponding reference characters indicate corresponding components throughout the several views of the drawings. Skilled artisans will appreciate that elements in the figures are illustrated for simplicity and clarity and have not necessarily been drawn to scale. For example, the dimensions of some of the elements in the figures may be exaggerated relative to other elements to help to improve understanding of various embodiments of the present invention. In addition, common but well-understood elements that are useful or necessary in a commercially feasible embodiment are often not depicted in order to facilitate a less obstructed view of these various embodiments of the present invention.

### DESCRIPTION OF THE EMBODIMENTS

The following describes embodiments of the present disclosure in detail with reference to the drawings. One skilled in the relevant art will recognize, however, that the techniques described herein may be practiced without one or more of the specific details, or with other methods, components, materials, etc. In other instances, well-known structures, materials, or operations are not shown or described in detail to avoid obscuring certain aspects. It is to be noted that the following embodiments do not limit the present disclosure. In addition, a configuration obtained by selectively combining a plurality of examples is also included in the present disclosure.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

The term “configured (or set) to” may be interchangeably used with the term, for example, “suitable for”, “having the capacity to”, “designed to”, “adapted to”, “made to”, or “capable of”. The term “configured (or set) to” may not necessarily have the meaning of “specifically designed to”. In some cases, the term “device configured to” may indicate that the device “may perform” together with other devices or components. For example, the term “processor configured (or set) to perform A, B, and C” may represent a dedicated processor (e.g., an embedded processor) for performing a corresponding operation, or a generic-purpose processor (e.g., a CPU or an application processor) for executing at least one item of software or program stored in a memory device to perform a corresponding operation.

It is appreciated that the term “about” and the term “substantially” may refer to a value of a given quantity or manufacturing parameters that varies within 5% of the value (e.g., ±1%, ±2%, ±3%, ±4%, ±5% of the value). These values are merely examples and are not intended to be limiting. The terms “about” and “substantially” may refer to a percentage of the values as interpreted by those skilled in relevant art(s) in light of the teachings of the present disclosure.

It will be understood that, although the terms first, second, third, etc., may be used in the disclosure and claims to describe various elements, these elements should not be limited by these terms and should not be used to determine the process sequence or formation order of associated elements. Unless indicated otherwise, these terms are merely used to distinguish one element from another element. Thus, a first element discussed below could be termed a second element without departing from the teachings of the disclosed embodiments.

Spatially relative terms, such as “beneath,” “below,” “over,” “under,” “above,” “upper,” “top,” “bottom,” “left,” “right,” “center,” “middle,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is rotated or turned over, elements described as “below” or “beneath” or “under” other elements or features would then be oriented “above” the other elements or features. Thus, the exemplary terms “below” and “under” may encompass both an orientation of above and below. The device may be otherwise oriented (rotated ninety degrees or at other orientations) and the spatially relative descriptors used herein interpreted accordingly. In addition, it will also be understood that when an element is also referred to as being “between” two other elements, it may be the only element between the two other elements, or one or more intervening elements may also be present.

Throughout this specification, several terms of art are used. These terms are to take on their ordinary meaning in the art from which they come, unless specifically defined herein or the context of their use would clearly suggest otherwise. It should be noted that element names and symbols may be used interchangeably through this document (e.g., Si vs. silicon); however, both have identical meaning.

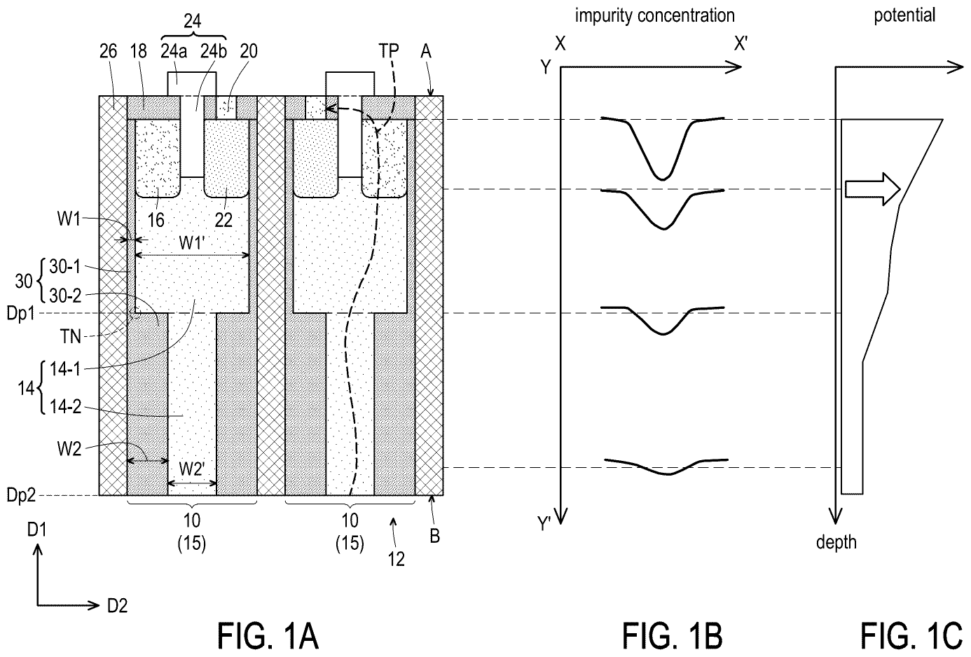

FIG. 1A is a cross-sectional view of a pixel structure according to some embodiments of the present disclosure. The illustrated pixel structure incudes two pixels 10 of a pixel array of an image sensor, and the pixel array (not shown) may include a plurality of pixels 10 arranged into a plurality of rows and a plurality of columns. The image sensor may be a backside illuminated sensor (BSI) and/or a solid state image sensor. In some embodiments, the pixel 10 is disposed in a pixel region and formed in a semiconductor substrate 12. The pixel 10 has a first surface A and a second surface B opposite to the first surface A. In the illustrated embodiments, the first surface A is also referred to as front surface, and the second surface B is also referred to as rear or backside surface opposite to the front surface. In embodiments where the image sensor is a backside illuminated image sensor, the first surface may also be referred as non-illuminated surface and the second surface may be referred as illuminated surface. FIG. 1A may be a cross-sectional view taken in a plane that perpendicular to the first surface A (e.g., front surface). The plane may be formed by a first direction D1 and a second direction D2 substantially perpendicular to the first direction D1. Each of the first direction D1 and the second direction D2 is substantially perpendicular to the first surface A and the second surface B, for example. The first direction D1 may be also referred to as depthwise direction, depth direction or vertical direction, and the second direction D2 may be also referred to as transverse direction, width direction or horizontal direction.

It is appreciated that the semiconductor substrate 12 may be a semiconductor wafer (e.g., a silicon wafer). In some embodiments, the semiconductor substrate 12 includes or is otherwise formed of silicon (e.g., single crystal silicon), a silicon germanium alloy, germanium, silicon carbide (SiC), a silicon carbide alloy, an indium gallium arsenide alloy, any other alloys formed of III-V group compounds, combinations thereof, one or more epitaxial layers of the aforementioned materials, or a bulk substrate thereof. More specifically, the semiconductor substrate 12 may be any semiconductor material or combination of materials that may be doped or otherwise configured to facilitate formation of a photo-sensitive region of the respective pixel. In some embodiments, the semiconductor substrate 12 may include or be one or more epitaxial layers (e.g., p- or n-doped silicon) formed on a carrier or a base substrate wafer (e.g., support wafer). In such embodiments, photodiodes, floating diffusion regions, source/drain regions or the like included in a respective pixel or pixel cell may be formed in the one or more epitaxial layers in or of the semiconductor substrate 12, and the carrier or the base substrate wafer (e.g., support wafer) may be removed or otherwise thinned during the fabrication.

In the illustrated example, the semiconductor substrate 12 includes a semiconductor layer 14. The semiconductor layer 14 may be a doped region, an epitaxially grown semiconductor layer on the semiconductor substrate 12 or the like of the semiconductor substrate 12. The semiconductor layer 14 may include impurities of first conductive type, and thus the semiconductor layer 14 may be of the first conductive type. The first conductive type may be n-type, and the n-type impurities may be phosphorus (P), arsenic (As), antimony (Sb), and the like. In some embodiments, the semiconductor layer 14 may be a doped region formed by performing a doping process with n-type impurities on the semiconductor substrate 12. For example, the semiconductor layer 14 is a deep n-type region. In some embodiments, the semiconductor layer 14 may be a single-crystal layer formed by an epitaxial growth process and an in-situ doping process with n-type impurities. For example, the semiconductor layer 14 is an n-type doped epitaxial layer. The semiconductor layer 14 may also be a part of or a region of a photodiode 15 and configured to photo-generate electric charges (e.g., electrons) corresponding to an incident light. In other words, the semiconductor layer 14 may be part of a photo-sensitive region or a photodiode region of the photodiode. The photodiode may be configured to receive the incident light through the second surface (e.g., rear or backside surface) B.

The pixel 10 further includes a doped region 16. The doped region 16 may be of the first conductive type. In other words, the semiconductor layer 14 and the doped region 16 are of the same conductive type such as n-type. In some embodiments, the doped region 16 is formed above (e.g., on the upper surface side of) the semiconductor layer 14. In other words, the doped region 16 may be disposed or otherwise formed between the first surface A and the semiconductor layer 14. In some embodiments, the doped region 16 has an impurity concentration (e.g., n-type impurity concentration) greater than that of the semiconductor layer 14.

In some embodiments, the pixel 10 further includes a front surface region 18, and the front surface region 18 may be formed above (e.g., on the upper surface side of) the semiconductor layer 14. For example, the front surface region 18 may be disposed or otherwise form between the first surface A and the semiconductor layer 14. The front surface region 18 may be of a second conductive type opposite to the first conductive type. The front surface region 18 in some embodiments may be grounded. The second conductive type may be p-type, and the p-type impurities may be boron (B), aluminum (Al), gallium (Ga), indium (In), and the like. For example, the semiconductor layer 14 and the doped region 16 are of n-type while the front surface region 18 is of p-type. Thus, the semiconductor layer 14 and the doped region 16 may be also referred to as n-type semiconductor layer 14 and p-type doped region 16, and the front surface region 18 may be also referred to as front surface p-type region 18. In some embodiments, the pixel 10 further includes a floating diffusion region 20. The floating diffusion region 20 may be formed or otherwise disposed in a portion of the front surface region 18. The floating diffusion region 20 may be of the first conductive type, and the floating diffusion region 20 may have an impurity concentration that is greater than the semiconductor layer 14. For example, the floating diffusion region 20 has an n-type impurity concentration that is greater than an n-type impurity concentration of the semiconductor layer 14. In some embodiments, the pixel 10 further includes a well region 22. The well region 22 may be disposed between the floating diffusion region 20 and the semiconductor layer 14. For example, the well region 22 is provided below (e.g., on the lower surface side of) the floating diffusion region 20. The well region 22 may be of the second conductive type, in other words, the well region 22 has a conductive type opposite to the semiconductor layer 14, the doped region 16 and the floating diffusion region 20. The well region 22 may be disposed to provide isolation between the floating diffusion region 20 and the photodiode. The well region 22 may be also referred to as a cell well region. In some embodiments, the doped region 16 and the well region 22 are disposed at opposite sides of the pixel 10 and disposed at a similar depth. The well region 22 and the doped region 16 are respectively a deep well while the front surface region 18 is a shallow well, for example. However, the disclosure is not limited thereto. In other words, the pixel 10 may have any suitable configuration.

The pixel 10 further includes a transfer gate 24 disposed proximate to the first surface A of the semiconductor substrate 12. The transfer gate 24 is configured to selectively couple the doped region 16 to the floating diffusion region 20 for transferring photogenerated charges from the photodiode to the floating diffusion region 20 upon receiving transfer control signal (e.g., positive bias voltage). The transfer gate 24 may include a planar gate electrode 24a disposed proximate to the first surface A of the semiconductor substrate 12 and a vertical gate electrode 24b extending from the first surface A into the semiconductor layer 14. The planar gate electrode 24a and the vertical gate electrode 24b are physically connected and electrically connected, for example. The planar gate electrode 24a may extend on the first surface A along the second direction D2. For example, the planar gate electrode 24a extends over the front surface region 18 and covers a portion of the front surface region 18. The vertical gate electrode 24b may extend into the semiconductor layer 14 by a gate depth in the first direction D1 and may be disposed between the doped region 16 and the well region 22. A bottom surface of the vertical gate electrode 24b may be higher than bottom surfaces of the doped region 16 and the well region 22. For example, the bottom surface of the vertical gate electrode 24b is disposed between the first surface A and the bottom surfaces of the doped region 16 and the well region 22. Such a configuration causes the sidewall of the transfer gate 24 positioned between the doped region 16 and the floating diffusion region 20 to serve as a channel region. In addition, the configuration functions as a transfer transistor which may be turned on and off in accordance with a bias voltage applied to the transfer gate 24. The well region 22 may be configured to prevent electrons from flowing to the floating diffusion region 20 from the semiconductor layer 14, for example, by modulating impurity concentration. The planar gate electrode 24a and the vertical gate electrode 24b may be electrically isolated from the substrate regions of the semiconductor substrate 12, by an insulation layer functioning as gate dielectric (not shown).

In some embodiments, a trench isolation 26 is disposed or otherwise formed in the semiconductor layer 14 to surround each pixel and define a corresponding photo-sensitive region. From a top view, the trench isolation 26 is part of an interconnected (continuous) trench isolation grid, and the trench isolation grid may divide the semiconductor layer 14 into a plurality of pixel regions (e.g., surrounding regions) corresponding to each individual pixel 10. The trench isolation 26 is a deep trench isolation (DTI), for example. As shown in FIG. 1A, the trench isolation 26 surrounds and encloses the photo-sensitive region or photodiode region of the photodiode of the pixel 10. The trench isolation 26 extends from the first surface A toward the second surface B. In some embodiments, the trench isolation 26 includes an insulating material such as silicon nitride or silicon oxide to provide isolation between adjacent pixels. Alternatively, the trench isolation 26 may be formed by forming an insulating lining layer on a surface of the trench and filling the trench with dielectric material (such as oxide-based material). In other embodiments, the trench isolation 26 may be formed by forming an insulating lining layer on a surface of the trench and filling the trench with polysilicon material or suitable conductive material and kept at a predetermined potential. In some embodiments, the semiconductor substrate 12 may be removed or otherwise thinned during the fabrication such that the trench isolation 26 extends from the first surface (e.g., front surface) A and penetrates through the semiconductor layer 14 along the first direction D1. In other words, the trench isolation 26 may have an isolation depth that is substantially the same as a vertical thickness of the semiconductor layer 14.

In some embodiments, a doped region 30 is disposed or otherwise formed on the side of the trench isolation 26 within the pixel region. That is, the doped region 30 is disposed between the trench isolation 26 and the semiconductor layer 14. The doped region 30 may be in direct contact with the trench isolation 26 and the semiconductor layer 14. In some embodiments, the doped region 30 is disposed to surround the semiconductor layer 14 of the pixel 10 separating the trench isolation 26 from the semiconductor layer 14 of pixels 10. In some embodiments, the doped region 30 is doped with impurities having conductive type opposite to the semiconductor layer 14. For example, the semiconductor layer 14 is of the first conductive type while the doped region 30 is of the second conductive type. In some embodiments, the doped region 30 is doped with second conductive type impurities (e.g., p-type impurities such as boron). The doped region 30 may be also referred to as p-type doped region or deep p-type well. The doped region 30 is configured to have a varying width along the second direction D2. In some embodiments, the width W1, W2 of the doped region 30 along the second direction D2 decreases as the doped region 30 becomes closer to the first surface A.

In the illustrated embodiments, the doped region 30 includes a first portion (e.g., upper portion) 30-1 and a second portion (e.g., lower portion) 30-2. The first portion 30-1 of the doped region 30 is disposed or otherwise formed to extend from the first surface A to a first depth Dp1 with respect to first surface A toward the second surface B along the first direction D1, and the second portion 30-2 of the doped region 30 is disposed or otherwise formed between the first portion 30-1 and the second surface B along the first direction D1. In some embodiments, the second portion 30-2 of the doped region 30 extends from the first depth Dp1 to the second surface B, that is, the second portion 30-2 is in a directly contact with (e.g., directly below) the first portion 30-1. In some embodiments, the first portion 30-1 and the second portion 30-2 of the doped region 30 are integrally formed. In some embodiments, the second surface B is also referred to as second depth Dp2 with respect to the first surface A. For example, the second portion 30-2 of the doped region extends from the first depth Dp1 to the second depth Dp2. A first width W1 of the first portion 30-1 is configured to be less than a second width W2 of the second portion 30-2 in the second direction D2. In some embodiments, the first width W1 of the first portion 30-1 and the second width W2 may be respectively also referred to as lateral thickness on the trench isolation 26 along the second direction D2. The first portion 30-1 may have a constant or uniform width, that is, the first width W1 of the first portion 30-1 is substantially constant from the first surface A to the first depth Dp1. Similarly, the second portion 30-2 may have a constant width, that is, the second width W2 of the second portion 30-2 is substantially constant from the first depth Dp1 to the second surface B (e.g., second depth Dp2). In some embodiments, the first depth Dp1 with respect to the first surface A is about half of the second depth Dp2 with respect to the first surface A. For example, a vertical thickness of the first portion 30-1 is substantially equal to a vertical thickness of the second portion 30-2 along the first direction D1. However, the disclosure is not limited thereto.

In some embodiments, the trench isolation 26 is disposed between adjacent doped regions 30 separating adjacent pixels 10. Alternatively, the trench isolation 26 is sandwiched between adjacent doped regions 30 as illustrated in FIG. 1A. In some embodiments, the trench isolation 26 is disposed to enclose the doped region 30 and the photo-sensitive region of the photodiode within the pixel region of the pixel 10. The doped region 30 is disposed to surround the semiconductor layer 14 within one pixel region and passivate a sidewall surface of the trench isolation 26 of the trench isolation grid. Thus, the doped region 30 may be also referred to as well isolation structure (e.g., p-well isolation structure). In some embodiments, a thickness (e.g., vertical thickness) of the doped region 30 along the first direction D1 (e.g., depthwise direction), i.e., the combined thickness of the first portion 30-1 and the second portions 30-2, is substantially the same as the isolation depth of the trench isolation 26. In some embodiments, surfaces (e.g., bottom surfaces) of the doped region 30, the trench isolation 26 and the semiconductor layer 14 are substantially coplanar. For example, the surfaces (e.g., bottom surfaces) of the doped region 30, the trench isolation 26 and the semiconductor layer 14 are substantially coplanar with the second surface B. In some embodiments, surfaces (e.g., top surfaces) of the trench isolation 26, the front surface region 18 and the floating diffusion region 20 are substantially coplanar. For example, the surfaces (e.g., top surfaces) of the trench isolation 26, the front surface region 18 and the floating diffusion region 20 are substantially coplanar with the first surface A.

In some embodiments, the trench isolation 26 may be surrounded by doped region 30 of two adjacent pixels 10. In some embodiments, the semiconductor layer 14 is surrounded by the doped region 30. In some embodiments, the width W1′, W2′ of the semiconductor layer 14 along the second direction D2 increases as the semiconductor layer 14 becomes closer to the first surface A. In the illustrated embodiments, the semiconductor layer 14 includes a first region 14-1 (e.g., upper layer portion) surrounded by the first portion 30-1 of the doped region 30 and a second region 14-2 (e.g., lower layer portion) surrounded by the second portion 30-2 of the doped region 30. The first region 14-1 of the semiconductor layer 14 is disposed or otherwise formed to extend from first surface A to a first depth Dp1 toward the second surface B along the first direction D1, and the second region 14-2 of the semiconductor layer 14 is disposed or otherwise formed between the first region 14-1 and the second surface B along the first direction D1. For example, the second region 14-2 extends from the first depth Dp1 to the second surface B (e.g., second depth Dp2), that is, the second region 14-2 is in contact with (e.g., directly below) the first region 14-1. The first region 14-1 of the semiconductor layer 14 may be disposed at a substantially the same depth as the first portion 30-1 of the doped region with respect to first surface. The second region 14-2 of the semiconductor layer 14 may be disposed at a substantially the same depth as the second portion 30-2. A first width W1′ of the first region 14-1 is configured to be larger than a second width W2′ of the second region 14-2 in the second direction D2. In some embodiments, a total combined lateral width of the first portion 30-1 of the dope region and the first region 14-1 of the semiconductor layer 14 is substantially equal to a total combined lateral width of the second portion 30-2 of the doped region and the second region 14-2 of the semiconductor layer 14 along the second direction D2, that is, W1+W1′=W2+W2′. The first region 14-1 may have a constant width, that is, the first width W1′ of the first region 14-1 is substantially constant from the first surface A to the first depth Dp1. Similarly, the second region 14-2 may have a constant width, that is, the second width W2′ of the second region 14-2 is substantially constant from the first depth Dp1 to the second surface B (e.g., second depth Dp2).

The doped region 30 has an inner boundary interfacing the semiconductor layer 14 formed by junction between doped region 30 and the semiconductor layer 14 and an outer boundary interfacing the trench isolation 26. In some embodiments, due to the width difference between the portions of doped region 30 (e.g., first portion 30-1 and second portion 30-2 of the doped region 30), the inner boundary of the doped region 30 may have a turning point or width transition point TN between the portions (e.g., first portion 30-1 and second portion 30-2), where lateral width of doped region changes. Similarly, the semiconductor layer 14 also has width changes at the turning point TN between the portions (e.g., first region 14-1 and second region 14-2). In such embodiments, the boundary of the doped region 30 and the boundary of the semiconductor layer 14 have a step profile, in other words, the doped region 30 and the semiconductor layer 14 have a step boundary or staircase boundary. Alternatively, the interface between the doped region 30 and the semiconductor layer 14 have a step profile.

As will be described below, the doped region 30 may be formed by doping the semiconductor layer 14 with second conductive type impurities (e.g., p-type impurities). In some embodiments, the first portion 30-1 has a first impurity concentration of the second conductive type, the second portion 30-2 has a second impurity concentration of the second conductive type, and each of the first impurity concentration and the second impurity concentration is larger than an impurity concentration of the semiconductor layer 14. In some embodiments, the second impurity concentration of the second portion 30-2 is higher than the first impurity concentration of the first portion 30-1. Accordingly, in some embodiments where the doped region 30 is formed by doping the semiconductor layer 14 with the second conductive-type impurities, the counter doping causes a region impurity concentration of the second region 14-2 surrounded by the second portions 30-2 to be lower than a region impurity concentration of the first region 14-1 surrounded by the first portion 30-1. For example, the second region 14-2 closer to the second surface B has a region impurity concentration of the first conductive type lower than that of the first region 14-1 arranged away from the second surface B. In alternative embodiments, the second impurity concentration of the second portion 30-2 is substantially equal to the first impurity concentration of the first portion 30-1.

In some embodiments, the impurity concentration (e.g., n-type impurity concentration) of the semiconductor layer 14 is lower in the second region 14-2 and higher in the first region 14-1 than other regions of the semiconductor layer 14. In an embodiment in which the semiconductor layer 14 is formed by an epitaxial growth, the semiconductor layer 14 is doped with n-type impurities by an in-situ doping process. In such embodiment, an additional step (e.g., deep n-type impurity implantation) such as implanting ions with high energy may be omitted. Furthermore, in some embodiments, the formation of the doped region 30 (e.g., including first and second portions 30-1 and 30-2) allows the semiconductor layer 14 to have an impurity concentration gradient (e.g., n-type impurity concentration gradient). In other words, the formation of the doped portion (e.g., second portion 30-2) with a larger width (e.g., width W2) allows the semiconductor layer 14 adjacent thereto to have relatively low n-type impurity concentration. In contrast, the formation of the doped portion (e.g., first portion 30-1) with a smaller thickness (e.g., width W1) allows the semiconductor layer 14 adjacent thereto to have relatively high n-type impurity concentration. For example, the first region 14-1 has a higher n-type region impurity concentration than the second region 14-2. As such, the potential of the photodiode region may be configured. In some embodiments, the width W1 of the first portion 30-1 and the width W2 of the second portion 30-2 may be configured to modulate the potentials of the semiconductor layer 14 to optimize full well capacity and charge transfer efficiency.

FIG. 1B illustrates the first conductive type impurity concentration and the potentials of the semiconductor layer of the pixel of FIG. 1A in the second direction (e.g., transverse direction X→X′) at different regions along the first direction from the first surface to the second surface (e.g., depth direction Y→Y′ from a front surface (first surface A) to a rear or backside surface (second surface B)) according to some embodiments of the present disclosure. As shown in FIG. 1B, the first conductive type impurity concentration (e.g., n-type impurity concentration) increases and the potential increases toward the first surface A (e.g., front surface). In addition, the potential of the semiconductor layer 14 comes closer to zero as the doped region 30 is closer.

FIG. 1C illustrates the potentials of the semiconductor layer 14 in the second direction (e.g., transverse direction X→X′) near the middle of the pixel of FIG. 1A in the first direction D1 from the first surface to the second surface (e.g., depth direction Y→Y′ from a front surface to a rear or backside surface) according to some embodiments of the present disclosure. FIG. 1C represents the positive. As shown in FIG. 1C, the potential increases in the positive direction toward the first surface A (e.g., front surface) to attain a target full well capacity.

In some embodiments, the first conductive type impurity concentration (e.g., n-type impurity concentration) of the semiconductor layer 14 increases from the backside surface toward the front surface and form a potential gradient. Thus, when the electric charges (e.g., electrons) are photogenerated in response to an incident light and accumulated in the charge accumulation region formed of the semiconductor layer 14, the electric charges (e.g., electrons) may easily move to the front surface in accordance with the potential gradient. The electric charges (e.g., electrons) are transferred from the semiconductor layer 14 to the floating diffusion region 20 through the transfer transistor (including the doped region 16 and the front surface region 18) as indicated by the dashed line TP in FIG. 1A. In this configuration, biasing the transfer gate 24 at an H (high) level (e.g., positive bias voltage) may cause the transfer transistor to be turned on and allow transferring electric charges (e.g., electrons) from the doped region 16 to the floating diffusion region 20. On contrary, biasing the transfer gate 24 at a L (low) level (e.g., zero or negative bias voltage) may cause the transfer transistor to be turned off and prevent electric charges (e.g., electrons) from transferring to the floating diffusion region 20.

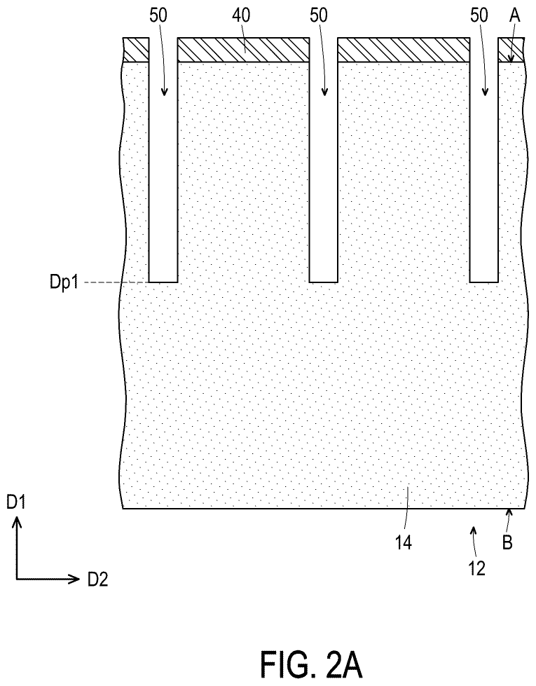

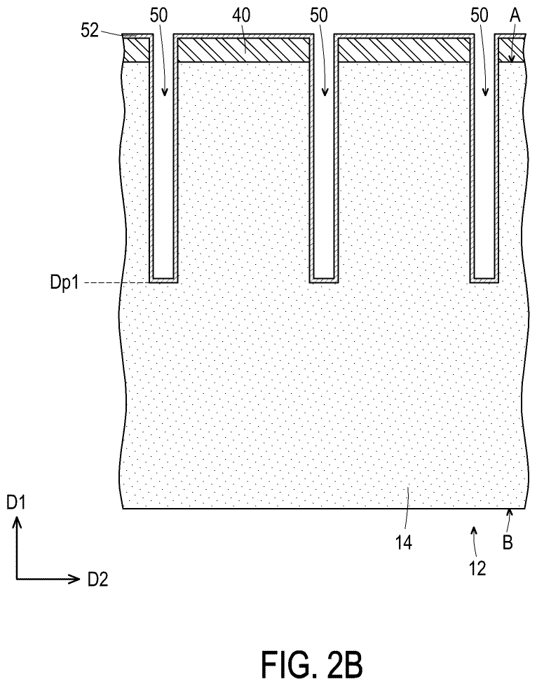

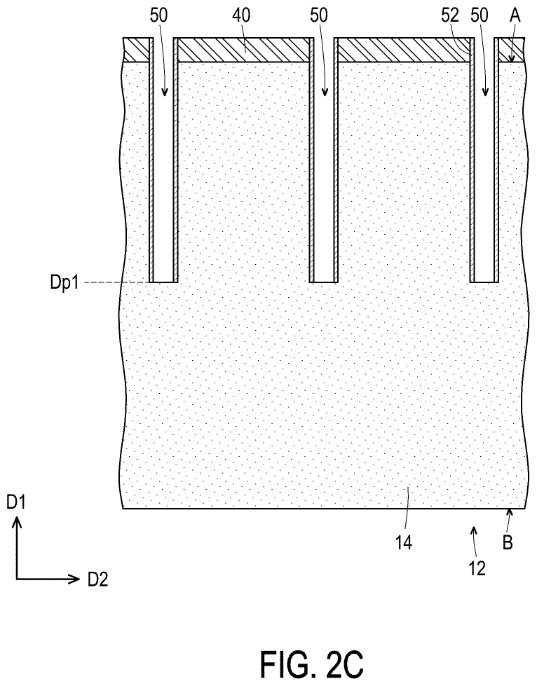

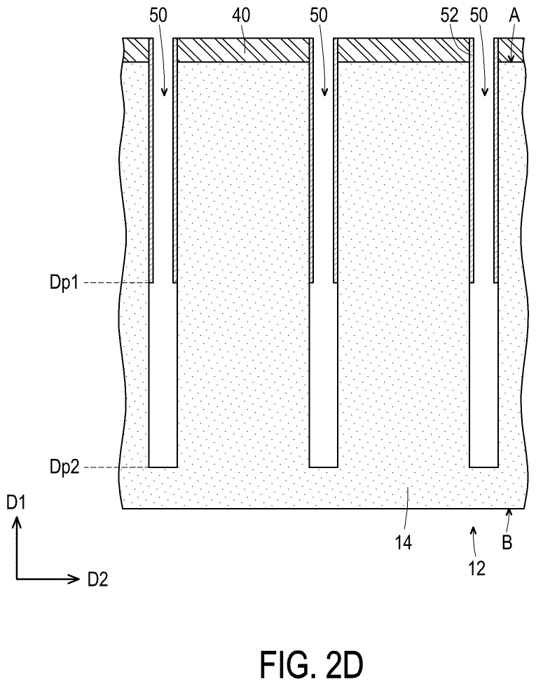

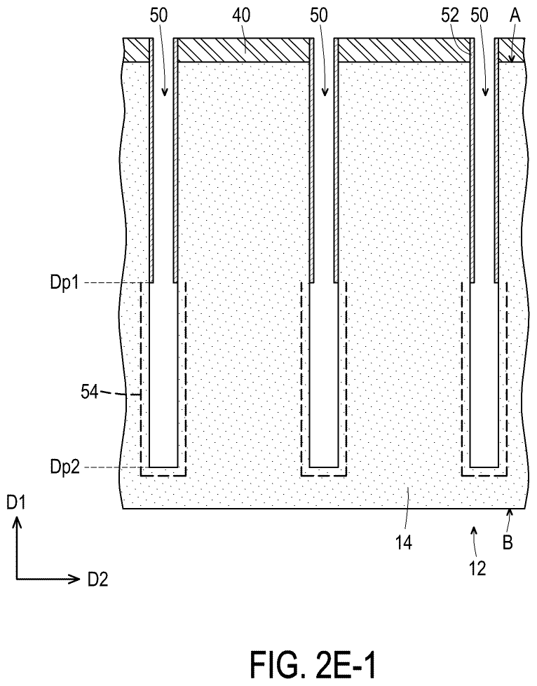

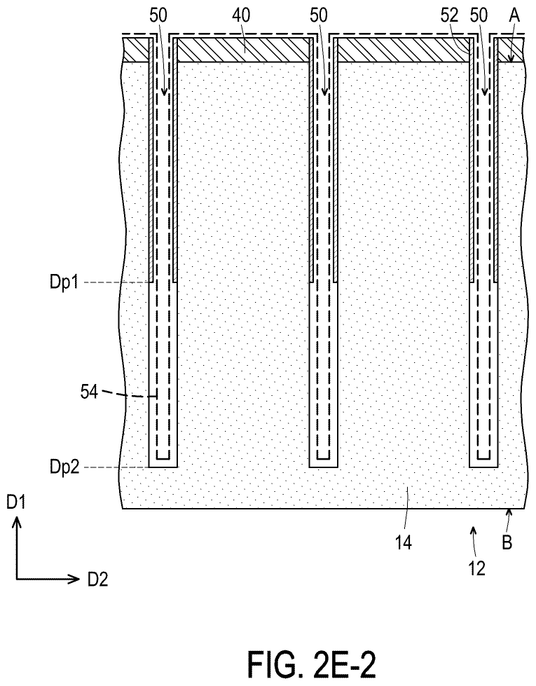

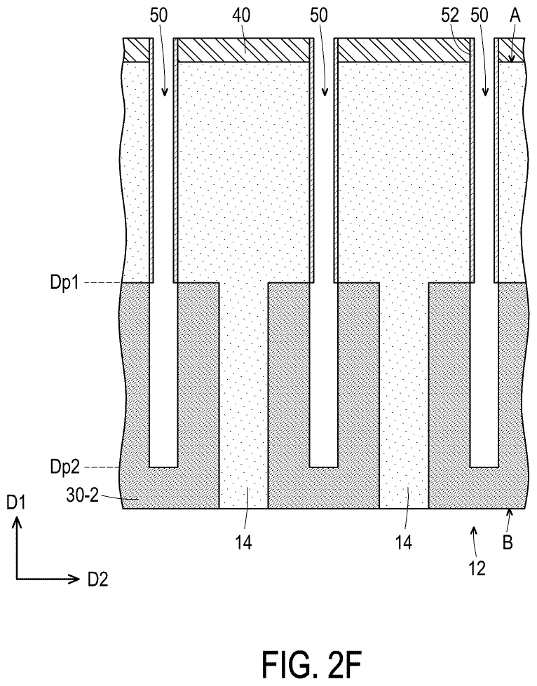

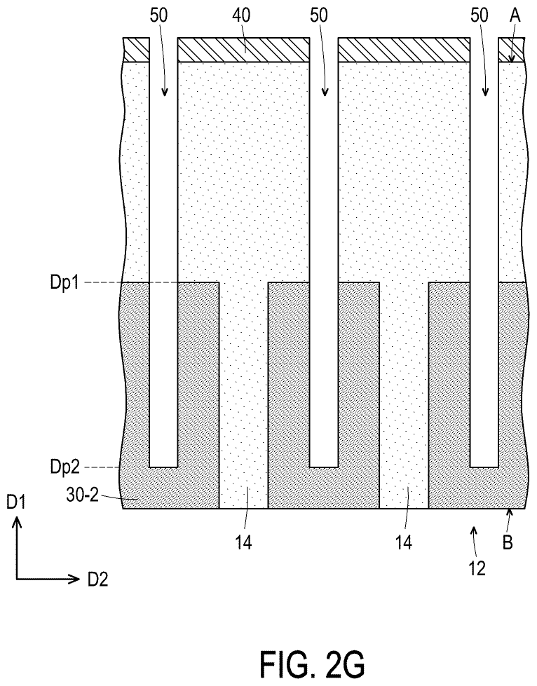

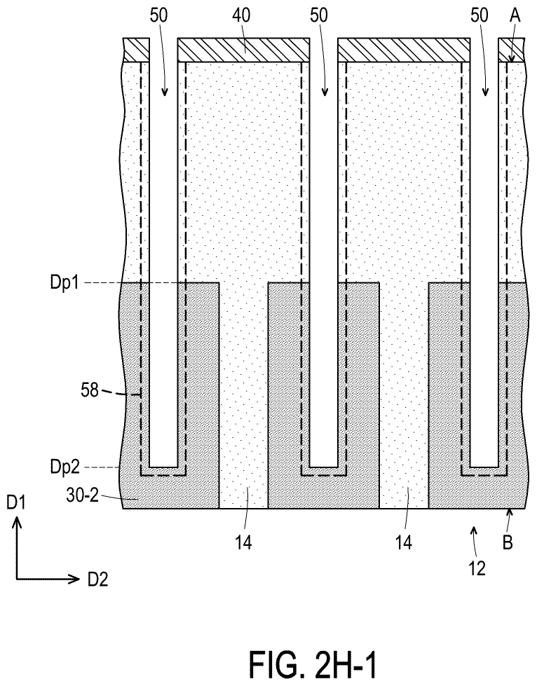

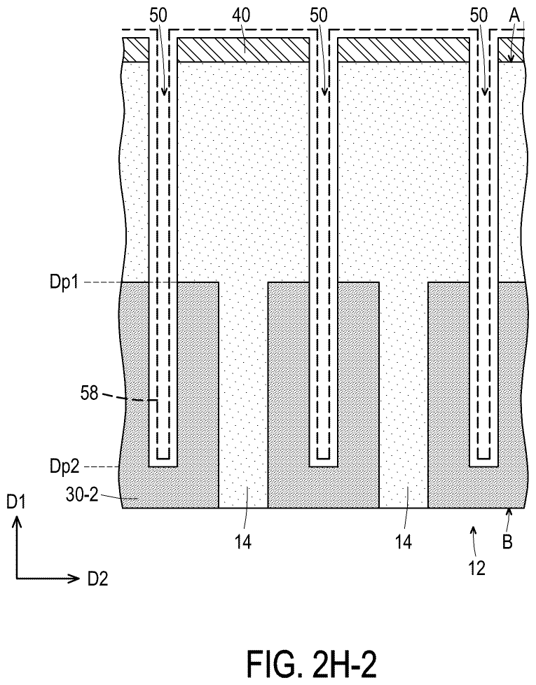

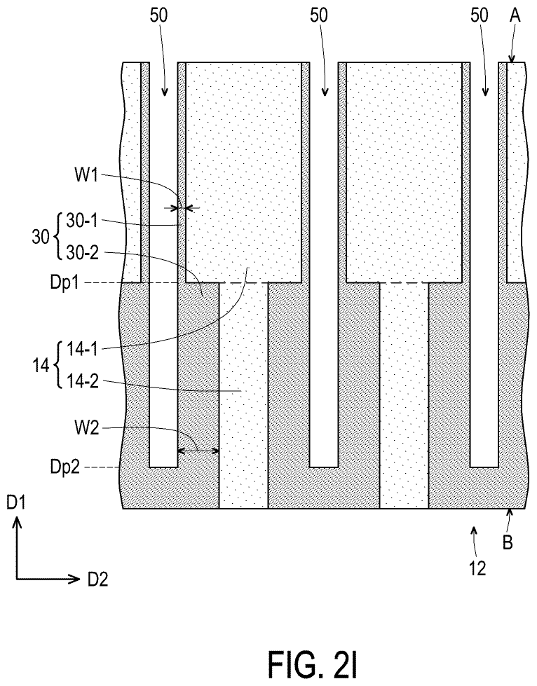

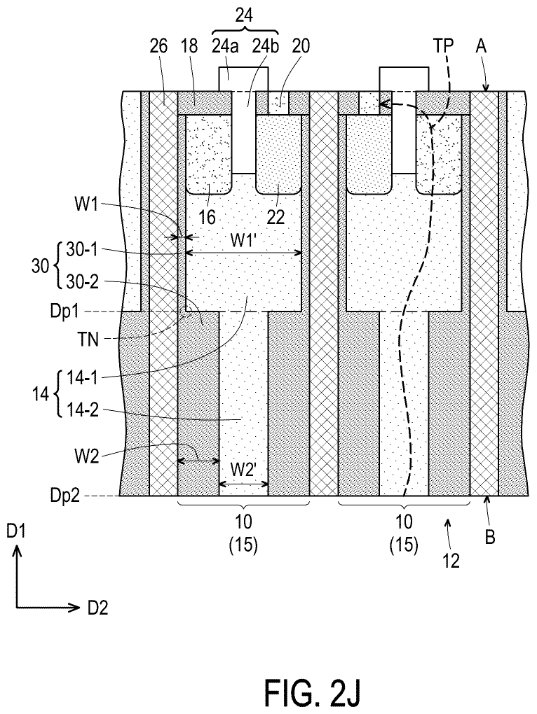

FIG. 2A to FIG. 2J illustrate cross-sectional views of a method of forming a pixel structure. The pixel structure of FIG. 2J is similar to that of FIG. 1A, and thus the elements (e.g., floating diffusion region 20, transfer gate 24, well isolation 22, semiconductor layer 14, trench isolation 26, and so on) of FIG. 2A to FIG. 2J may include similar features (such as composition, shape, structure, arrangement, distribution, combinations thereof and so on) to the elements of FIG. 1A and details thereof may be omitted.

Referring to FIG. 2A, a trench 50 and a semiconductor layer 14 of a first conductive type are formed in a semiconductor substrate 12, wherein the semiconductor layer 14 is surrounded by the trench 50. In some embodiments, the semiconductor substrate 12 includes the semiconductor layer 14 formed by an epitaxial growth and an in-situ doping process with first conductive type impurities (e.g., n-type impurities) in a predetermined concentration. The semiconductor layer 14 is of the first conductive type, for example, n-type. Then, a hard mask 40 and a photoresist (not shown) are sequentially formed on a first surface A of the semiconductor substrate 12 (e.g., semiconductor layer 14) and expose portions of the semiconductor layer 14 at the first surface (e.g., front surface) A. After that, the trench 50 is formed in the semiconductor layer 14 by removing portions of the semiconductor layer 14 exposed by the hard mask 40 with a wet etch and/or a dry etch. The trench 50 is an interconnected (continuous) trench and divides the semiconductor substrate 12 into a plurality of pixel regions for pixels, for example. The trench 50 may have a first depth (e.g., initial depth) Dp1 with respect to the first surface A along a first direction D1, and the first depth Dp1 is smaller than a thickness of the semiconductor substrate 12 (e.g., semiconductor layer 14). In some embodiments, the first depth Dp1 is substantially not larger than half of a total depth of a formed photodiode along depthwise direction. In some embodiments, the first depth Dp1 is about half of the total vertical depth of the formed photodiode along depthwise direction.

Referring to FIG. 2B, a stopper layer 52 is formed on a sidewall of the trench 50. In some embodiments, the stopper layer 52 may be a liner layer that is conformally formed on the exposed surfaces of the trench 50 and the hard mask 40. For example, the stopper layer 52 is conformally formed on a bottom surface and the sidewall of the trench 50 and a top surface and a sidewall of the hard mask 40. A material of the stopper layer 52 may include an insulating material such as silicon oxide, silicon nitride or a combination thereof. The stopper layer 52 may be formed by a deposition process, a coating process or the like with an appropriate lateral thickness along a second direction D2. The stopper layer 52 may be also referred to as stopper, stopper liner, dopant diffusion stopper layer or the like.

Referring to FIG. 2C and FIG. 2D, portions of the stopper layer 52 are removed. For example, the portions of the stopper layer 52 on the bottom surface of the trench 50 and the top surface of the hard mask 40 are removed. The stopper layer 52 may be removed by an etch process in the first direction (e.g., depth direction) D1. For example, the etch process is a vertical etch process. In some embodiments, during the partial removal of the stopper layer 52, a portion of the semiconductor layer 14 is also removed in the first direction (e.g., depth direction) D1. Thus, as shown in FIG. 2D, the trench 50 is further extended to a second depth Dp2 of the semiconductor substrate 12 (e.g., semiconductor layer 14) with respect to the first surface A along the first direction D1. The second depth Dp2 is larger than the first depth Dp1 with respect to first surface A and smaller than a total vertical thickness of the semiconductor substrate 12 (e.g., semiconductor layer 14). In some embodiments, the second depth Dp2 is substantially equal to the depth of the formed photodiode.

As shown in FIG. 2D, the trench 50 includes a first trench portion (e.g., upper trench portion) 50U between the first surface A and the first depth Dp1 and a second trench portion (e.g., lower trench portion) 50L between the first depth Dp1 and the second surface B. In some embodiments, the stopper layer 52 is formed on the inner sidewall of the first trench portion (e.g., upper trench portion) 50U and is not formed on the inner sidewall of the second trench portion (e.g., lower trench portion) 50L. In other words, the second trench portion (e.g., lower trench portion) 50L of the trench 50 is free of the stopper layer 52.

Referring to FIG. 2E-1 and FIG. 2E-2, after the formation of the stopper layer 52, second conductive type impurities 54 are formed adjacent to the trench 50. The second conductive type impurities 54 are p-type impurities, for example. In some embodiments, as shown in FIG. 2D and FIG. 2E-1, the second trench portion (e.g., lower trench portion) 50L of the trench 50 without the stopper layer 52 thereon is subjected to a plasma doping process with second conductive type impurities (e.g., p-type impurities such as boron). In such embodiments, the second conductive type impurities (e.g., p-type impurities) 54 are formed in a lower trench portion of the semiconductor layer 14 adjacent to the second trench portion (e.g., lower trench portion) 50L of the trench 50. In alternative embodiments, as shown in FIG. 2D and FIG. 2E-2, a semiconductor layer including the second conductive type impurities 54 is formed on the entire sidewall of the trench 50. For example, by a depositing process such as solid phase depositing process, the semiconductor layer including the second conductive type impurities 54 is formed on both the inner sidewall of the first trench portion (e.g., upper trench portion) 50U with the stopper layer 52 thereon and the inner sidewall of the second trench portion (e.g., lower trench portion) 50L without the stopper layer 52 thereon. The semiconductor layer 14 having the second conductive type impurities 54 is also referred to as second conductive type doping layer (e.g., p-type doped layer) or semiconductor layer doped with second conductive type impurities (e.g., semiconductor layer doped with p-type impurities), for example.

Referring to FIG. 2F, a second portion 30-2 of the second conductive type is formed in the semiconductor layer 14 adjacent to the trench 50. For example, the second conductive type impurities 54 (e.g., of FIG. 2E-1 or FIG. 2E-2) are diffused into the semiconductor layer 14 through sidewalls of the trench 50 to form the second portion 30-2. The second portion 30-2 extends from the first depth Dp1 to the second surface B, for example. The second conductive type impurities 54 may be diffused by an annealing process or the like. The second portion 30-2 is thus formed in the semiconductor layer 14 adjacent to the second trench portion (e.g., lower trench portion) 50L of the trench 50. In some embodiments, as shown in FIG. 2E-1 and FIG. 2F, the second conductive type impurities 54 doped alongside the second trench portion (e.g., lower trench portion) 50L without the stopper layer 52 thereon are diffused into the lower region (e.g., 14-2) of the semiconductor layer 14 to form the second portion 30-2. In alternative embodiments, as shown in FIG. 2E-2 and FIG. 2F, the second conductive type impurities 54 adjacent to the second trench portion (e.g., lower trench portion) 50L of the trench 50 without the stopper layer 52 thereon are diffused into the lower portion of the semiconductor layer 14 to form the second portion 30-2 while the diffusion of the second conductive type impurities 54 adjacent to the first trench portion (e.g., upper trench portion) 50U is blocked by the stopper layer 52. In some embodiments, the first conductive type impurity concentration (e.g., n-type impurity concentration) of the semiconductor layer 14 between the second portions 30-2 is lower than the first conductive type impurity concentration (e.g., n-type impurity concentration) of the semiconductor layer 14 thereabove because of the counter doping with the second conductive type impurities (e.g., p impurities).

Referring to FIG. 2G, the stopper layer 52 inside the trench 50 is then removed. The stopper layer 52 may be removed by an etch process such as a wet etch process or a dry etch process or the like.

Referring to FIG. 2H-1 and FIG. 2H-2, second conductive type impurities 58 are formed in proximity to the trench 50. For example, the second conductive type impurities 58 are formed adjacent to both the first trench portion (e.g., upper trench portion) 50U and the second trench portion (e.g., lower trench portion) 50L of the trench 50. In some embodiments, as shown in FIG. 2G and FIG. 2H-1, the second conductive type impurities (e.g., p-type impurities (e.g., boron)) 58 are formed in a portion of the semiconductor layer 14 adjacent to the entire sidewall of the trench 50 by a plasma doping process. In alternative embodiments, as shown in FIG. 2G and FIG. 2H-2, a semiconductor layer including the second conductive type impurities 58 may be formed on the entire sidewall of the trench 50 by a solid phase depositing process. The semiconductor layer including the second conductive type impurities 58 is also referred to as second conductive type doping layer (e.g., p-type doped layer) or a semiconductor layer doped with second conductive type impurities (e.g., semiconductor layer doped with p-type impurities), for example.

Referring to FIG. 2I, the second conductive type impurities 58 (e.g., of FIG. 2H-1 or FIG. 2H-2) are diffused into the semiconductor layer 14 to form a first portion 30-1. The first portion 30-1 and the second portion 30-2 form a doped region 30. In some embodiments, as shown in FIG. 2H-1 or FIG. 2H-2 and FIG. 2I, by an annealing process, the second conductive type impurities 58 adjacent to the first trench portion (e.g., upper trench portion) 50U may diffuse into the surrounding regions of semiconductor layer 14 between the second portion 30-2 and the first surface A to form the first portion 30-1 of the doped region 30. In some embodiments, a width of the second portion 30-2 of FIG. 2I may be substantially the same as a width of the second portion 30-2 of FIG. 2H-1 or FIG. 2H-2. However, the disclosure is not limited thereto. In alternative embodiments, the second conductive type impurities in the second portion 30-2 may be also diffused into the semiconductor layer 14, in other words, the second portion 30-2 may extend along the second direction D2. In such embodiments, the width of the second portion 30-2 of FIG. 2I may be (e.g., slightly) different from the width of the second portion 30-2 of FIG. 2H-1 or FIG. 2H-2. In some embodiments in which the second conductive type is p-type, the first portion 30-1 and the second portion 30-2 of the doped region 30 are p-type doped regions and are collectively referred to as p-type doped region 30. The above method may allow the second portion 30-2 to have width and impurity concentration different from the first portion 30-1. Thus, the doped region 30 may have at least two portions 30-1, 30-2 with different widths and impurity concentrations. In some embodiments, the second portion (e.g., wide portion) 30-2 is formed at the lower side of the doped region 30 adjacent to the second trench portion (e.g., lower trench portion) 50L of the trench 50, and the first portion (e.g., narrow portion) 30-1 is formed at the upper side of the doped region 30 adjacent to the first trench portion (e.g., upper trench portion) 50U of the trench 50. The first portion 30-1 is disposed on the second portion 30-2 along the first direction D1 (e.g., depth direction). The first portion 30-1 and second portion 30-2 may be monolithically formed within the semiconductor layer 14 of the semiconductor substrate 12 and an interface therebetween does not exist or not be observed. In some embodiments, there may be more implantation and annealing processes employed to form the second portion 30-2 than the first portion 30-1 of the doped region 30 such that a width (e.g., region width) and/or the impurity concentration of the second portion 30-2 is greater than that of the first portion 30-1. The above method makes it possible to form the doped region 30 having dual thickness.

Referring to FIG. 2J, one or more transistors are formed on the first surface (e.g., front surface) A. A trench isolation 26 is formed in the trench 50. The trench isolation 26 may be formed by filling an insulating material and/or conductive material in the trench 50 and removing a portion of the insulating material outside the trench 50. A thinning process such as chemical polishing process may be performed from the second surface (e.g., rear or backside surface) B to decrease the thickness of the semiconductor substrate 12 (e.g., semiconductor layer 14), such that a photodiode region may have a desired thickness (e.g., second depth Dp2). In some embodiments, after the thinning process, the trench isolation 26 may have a structure depth that is substantially the same as the thickness of the semiconductor layer 14. In alternative embodiments in which the semiconductor substrate 12 includes other layer than the semiconductor layer 14 and not removed during the thinning process, the trench isolation 26 may have a structure depth that is substantially the same as the combined thickness of the remained semiconductor substrate 12 and the semiconductor layer 14 thereover after the thinning process.

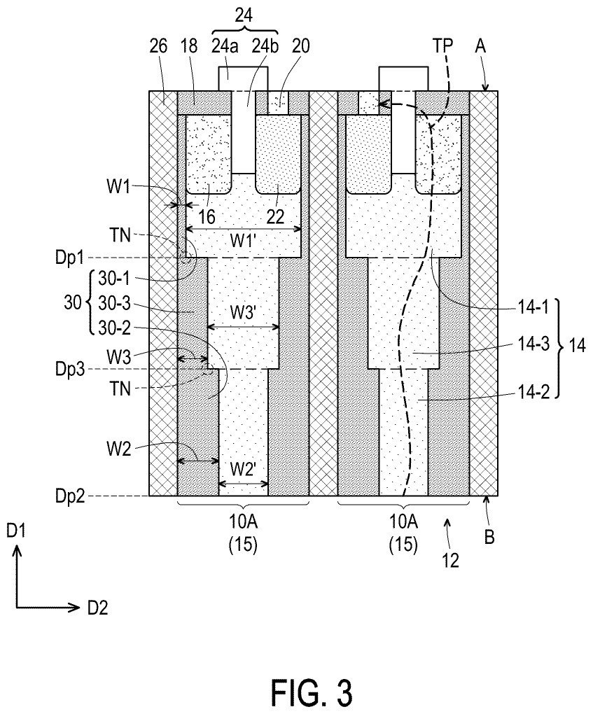

FIG. 3 is a cross-sectional sectional view of a pixel structure according to some embodiments of the present disclosure. The pixel structure of FIG. 3 is similar to that of FIG. 1A, and thus the elements (e.g., floating diffusion region 20, transfer gate 24, well isolation 22, semiconductor layer 14, trench isolation 26, and so on) of FIG. 3 may include similar features (such as composition, shape, structure, arrangement, distribution, combinations thereof and so on) to the elements of FIG. 1A and details thereof may be omitted. The difference between the will be described below. In some embodiments, at least one additional portion is disposed between the first portion 30-1 and the second portion 30-2 included in, and a doped region 30 of a pixel 10A includes multiple widths. For example, as shown in FIG. 3, a third portion 30-3 is disposed between the first portion 30-1 and the second portion 30-2, and the doped region 30 may include three different widths between first surface A and second surface B. In some embodiments, the first portion 30-1 (e.g., upper portion) is disposed or otherwise formed to extend from the first surface A to a first depth Dp1 toward the second surface B. The third portion 30-3 (e.g., intermediate portion) may be disposed or otherwise formed to extend from the first depth Dp1 toward the second surface B to a third depth Dp3. The second portion 30-2 (e.g., bottom portion) may be disposed or otherwise formed to extend from the third depth Dp3 to the second surface B (e.g., second depth Dp2). In some embodiments, the third portion 30-3 is disposed between and in direct contact with the first portion 30-1 and the second portion 30-2. For example, the first portion 30-1, the third portion 30-3 and the second portion 30-2 are continuously disposed from the first surface A to the second surface B.

In some embodiments, the first, second and third portions 30-1, 30-2, 30-3 respectively have first, second and third widths W1, W2, W3 along the second direction D2, the first width W1 is less than the second width W2, and the third width W3 is between the first width W1 and the second width W2. In other words, the width W1, W2, W3 of the doped region 30 decreases as the doped region 30 becomes closer to the first surface A. In some embodiments, the first portion 30-1 of the doped region 30 has a substantially uniform width (e.g., width W1) between the first surface A and the first depth Dp1. The third portion 30-2 of the doped region 30 may have a substantially uniform width (e.g., width W3) between the first depth Dp1 and the third depth Dp3. The second portion 30-2 of the doped region 30 may have a substantially uniform width (e.g., width W2) between the third depth Dp3 and the second surface B (e.g., second depth Dp2).

In some embodiments, the first to third portions 30-1, 30-2, 30-3 respectively have first, second and third impurity concentrations of the second conductive type (e.g., p-type impurity concentration), each of the first, second and third impurity concentrations is larger than an impurity concentration of the second conductive type (e.g., p-type impurity concentration) of the semiconductor layer 14. In some embodiments, the first impurity concentration of the first portion 30-1 is smaller than the second impurity concentration of the second portion 30-2, and the third impurity concentration of the third portion 30-3 is between the first impurity concentration and the second impurity concentration. That is, the impurity concentration of the doped region 30 decreases as the doped region 30 becomes closer to the first surface A. However, the disclosure is not limited thereto. In alternative embodiments, the impurity concentration of the doped region 30 is substantially the same from the first surface A to the second surface B, that is, the first, second and third impurity concentrations of the first to third portions 30-1, 30-2, 30-3 are substantially equal.

In the illustrated embodiments, the semiconductor layer 14 includes a first region 14-1 (e.g., upper layer region) surrounded by the first portion 30-1, a third region 14-3 (e.g., intermediate layer portion) surrounded by the third portion 30-1, and a second region 14-2 (e.g., lower or bottom layer portion) surrounded by the second portion 30-2. The first region 14-1 (e.g., upper layer portion) is disposed or otherwise formed to extend from the first surface A to a first depth Dp1 toward the second surface B. The third region 14-3 (e.g., intermediate layer portion) is disposed or otherwise formed to extend from the first depth Dp1 toward the second surface B to a third depth Dp3. The third region 14-3 (e.g., intermediate layer portion) may couple the first region 14-1 to the second region 14-2. The second region 14-2 (e.g., lower or bottom layer portion) is disposed or otherwise formed to extend from the third depth Dp3 to the second surface B (e.g., second depth Dp2). In some embodiments, the third region 14-3 is disposed between and in direct contact with the first region 14-1 and the second region 14-2. For example, the first region 14-1, the third region 14-3 and the second region 14-2 are continuously disposed from the first surface A to the second surface B. The first region 14-1 of the semiconductor layer 14 may be disposed at a substantially the same depth as the first portion 30-1 of the doped region 30, the third region 14-3 of the semiconductor layer 14 may be disposed at a substantially the same depth as the third portion 30-3 of the doped region 30, and the second region 14-2 of the semiconductor layer 14 may be disposed at a substantially the same depth as the second portion 30-2 of the doped region 30. A first width W1′ of the first region 14-1 is larger than a second width W2′ of the second region 14-2 in the second direction D2, and a third width W3′ of the third region 14-3 is between the first width W1′ and the second width W2′. In some embodiments, a total combined lateral width of the first portion 30-1 of the doped region and the first region 14-1 is substantially equal to a total combined lateral width of the second portion 30-2 of the doped region and the second region 14-2 of the semiconductor layer 14 and a total width of the third portion 30-3 of the doped region 30 and the third region 14-3 of the semiconductor layer 14 respectively, that is, W1+W1′=W2+W2′=W3+W3′. The first region 14-1 may have a constant or uniform width, that is, the first width W1′ of the first region 14-1 is substantially constant from the first surface A to the first depth Dp1. Similarly, the third region 14-3 may have a constant or uniform width, that is, the third width W3′ of the third region 14-3 is substantially constant from the first depth Dp1 to the third depth Dp3. The second region 14-2 may have a constant or uniform width, that is, the second width W2′ of the second region 14-2 is substantially constant from the third depth Dp3 to the second surface B (e.g., second depth Dp2).

In some embodiments, due to the width difference between the first to third portions 30-1, 30-2, 30-3 of the doped region 30, the inner boundary of the doped region 30 has turning points TN between adjacent two of the first to third portions 30-1, 30-2, 30-3. Similarly, a boundary of the semiconductor layer 14 facing the doped region 30 also have the turning points TN between adjacent two of the first to third regions 14-1, 14-2, 14-3. In such embodiments, the inner boundary of the doped region 30 and the boundary of the semiconductor layer 14 may be also referred to as step boundary or staircase boundary.

In some embodiments, the configuration of the doped region 30 makes the first conductive type (e.g., n-type) impurity concentration gradient of the semiconductor layer 14 gentler and smooths the movement of electric charges (e.g., electrons). In particular, in some embodiments in which a photodiode has long depth in the depthwise direction, the doped region having multiple widths is more preferable. Further, in alternative embodiments, the doped region may have more than three portions/widths and thus the semiconductor layer 14 may have more than three portions/widths. In such embodiments, the first conductive type (e.g., n-type) impurity concentration gradient may be further gentler.

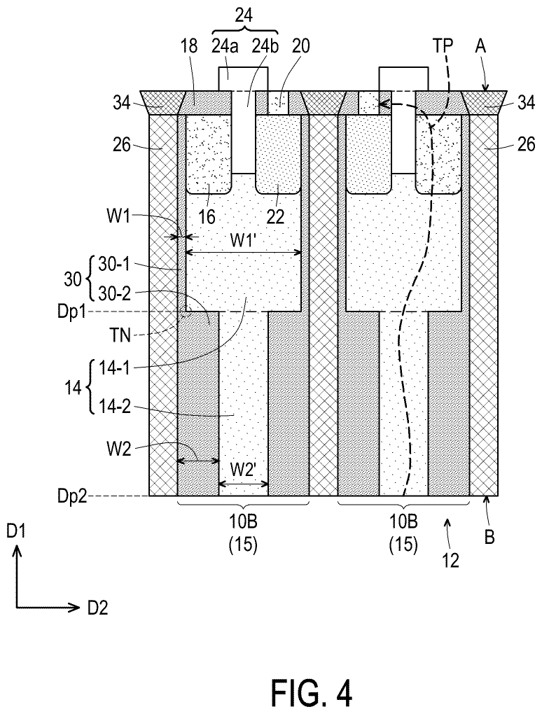

FIG. 4 is a cross-sectional sectional view of a pixel structure according to some embodiments of the present disclosure. The pixel structure of FIG. 4 is similar to that of FIG. 1A, and thus the elements (e.g., floating diffusion region 20, transfer gate 24, well isolation 22, semiconductor layer 14, trench isolation 26, and so on) of FIG. 4 may include similar features (such as composition, shape, structure, arrangement, distribution, combinations thereof and so on) to the elements of FIG. 1A and details thereof may be omitted. The difference between the will be described below. In some embodiments, the pixel 10B further includes a shallow trench isolation 34 disposed on a side of the front surface region 18 (e.g., front surface p-type region 18). For example, the shallow trench isolation 34 is disposed on the trench isolation 26 and surrounds the front surface region 18. In some embodiments in which the trench isolation 26 is a deep trench isolation (DTI), the shallow trench isolation 34 and/or the front surface region 18 may serve as a surface portion (e.g., an extended portion) of the trench isolation 26.

In some embodiments, by separately providing the shallow trench isolation 34 on the surface side (e.g., front surface side) of the trench isolation 26, it is possible to achieve the isolation between pixels more reliably. Furthermore, as shown in FIG. 4, a lateral width of the shallow trench isolation 34 may be configured to be larger than a lateral width of the trench isolation 26 therebelow or the shallow trench isolation 34 may be formed by using a material having different quality from the trench isolation 26. Thus, it is possible to achieve desired insulation performance at the first surface (e.g., front surface) A. In addition, the formation of the shallow trench isolation 34 at the first surface (e.g., front surface) A may also make it possible to alleviate/mitigate the electric field at P-N junction between the first portion 30-1 of the doped region 30 (e.g., p-doped region) and the floating diffusion region 20 (e.g., n-doped region).

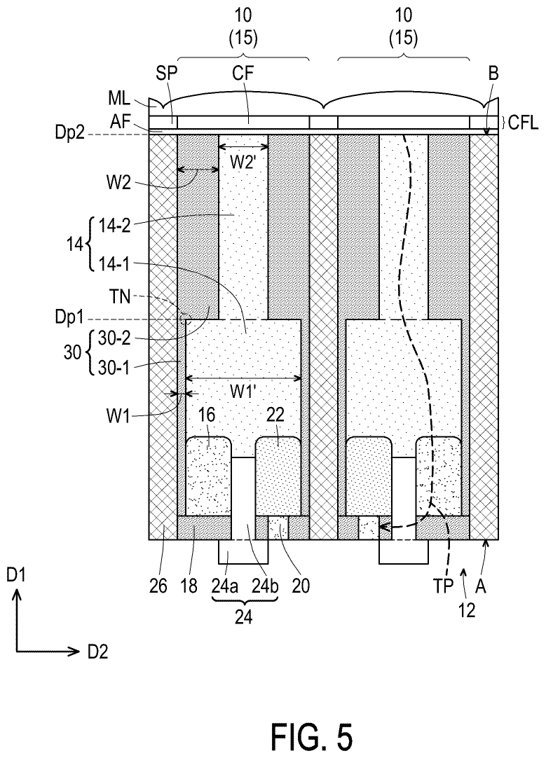

FIG. 5 is a cross-sectional sectional view of an image sensor according to some embodiments of the present disclosure.

Referring to FIG. 5, in some embodiments, an image sensor 10 includes a pixel array PA, an anti-reflective layer AF, a color filter layer CFL and a micro-lens layer ML. The image sensor 10 may be a backside illuminated sensor (BSI) and/or a solid state image sensor. The pixel array PA includes a plurality of pixels 10 of FIG. 1A, and the pixels 10 are arranged into a plurality of rows and a plurality of columns to form an array. The pixel 10 may have a size smaller than a micron such as less than 0.8 μm, 0.7 μm. In alternative embodiments, the pixel may be the pixel 10A, 10B of FIG. 3, FIG. 4 or the like. The color filter layer CFL is disposed on a surface of the pixel array PA (e.g., second surface B of the pixel 10), and includes a plurality of color filters CF and a separating pattern SP between the color filters CF, for example. The color filters CF may each have one color of blue, green, and red, and the separating pattern SP may be a low-refractive pattern. The color filters CF are disposed corresponding to the pixels 10 respectively, and the separating pattern SP is disposed corresponding to the trench isolation 26. For example, the color filters CF overlap the pixels 10 therebelow, and the separating pattern SP overlaps the trench isolation 26 therebelow. The anti-reflective layer AF is disposed between the pixel array PA and the color filter layer CFL and is formed of or include silicon oxide, for example. The micro-lens layer ML is disposed on the color filter layer CFL directing incident light toward the photodiode of the respective pixel 10. The micro-lens layer ML may include a micro-lens array and include convex lens portions respectively overlap the pixels 10 of the pixel array PA.

In some embodiments, based on the above, a pixel allows a photodiode to have a potential gradient, which may facilitate the movement of electric charges (e.g., electrons) in the photodiode. That is, by configuring the doped region 30 (e.g., p-type doped region) with different widths and concentrations, it may be possible to modulate the potential of the photodiode and set the full well capacity (FWC) and the degree of the movement of electric charges (e.g., electrons).

In some embodiments, the formation of the doped region (e.g., p-type doped region) 30 is in adjacent to sidewalls of the deep trench isolation makes it possible to passivate the silicon interface of the sidewall of the trench. Accordingly, the occurrence of white pixels may be reduced. In some embodiments, the photodiode is allowed to have a potential gradient, and thus the depth of the semiconductor layer may be further increased. Thus, it is possible for a photodiode to detect light having a long wavelength and thus the photodiode is suitable for applying in a security sensor or the like that uses light having a long wavelength. In some embodiments, it is possible to achieve a photodiode having a doping profile that yields target potential gradient facilitating the movement of electric charges (e.g., electrons) from photodiode to the floating diffusion region without deeply implanting n-type impurities such as arsenic or phosphorus using multiple high implantation energies, thereby effectively reduces ion-implantation-induced damage to the semiconductor substrate and shortens processing time (e.g., reducing loading time).

The above description of illustrated examples of the invention, including what is described in the Abstract, is not intended to be exhaustive or to limit the invention to the precise forms disclosed. While specific examples of the invention are described herein for illustrative purposes, various modifications are possible within the scope of the invention, as those skilled in the relevant art will recognize.

These modifications may be made to the invention in light of the above detailed description. The terms used in the following claims should not be construed to limit the invention to the specific examples disclosed in the specification. Rather, the scope of the invention is to be determined entirely by the following claims, which are to be construed in accordance with established doctrines of claim interpretation.

What is claimed is:

1. A pixel structure, comprising:
a semiconductor substrate having a first surface and a second surface opposite to the first surface;
a trench isolation in the semiconductor substrate;
a semiconductor layer disposed in the semiconductor substrate and surrounded by the trench isolation, wherein the semiconductor layer has a first conductive type and a photodiode is formed in the semiconductor layer; and
a doped region disposed between the trench isolation and the semiconductor layer, the doped region having a second conductive type opposite to the first conductive type, wherein the doped region extends between the first surface and the second surface, and a width of the doped region decreases as the doped region becomes closer to the first surface.

2. The pixel structure according to claim 1, wherein the doped region comprises:
a first portion extending from the first surface to a first depth with respect to the first surface along a first direction, the first portion having a first width in a second direction substantially perpendicular to the first direction; and
a second portion disposed between the first portion and the second surface, the second portion having a second width in the second direction,
wherein the first width is less than the second width.

3. The pixel structure according to claim 2, wherein the first portion has the first width which is substantially constant from the first surface to the first depth, and the second portion has the second width which is substantially constant from the first depth to the second surface.

4. The pixel structure according to claim 2, wherein the semiconductor layer comprises:
a first region, surrounded by the first portion of the doped region and the first region of the semiconductor layer having a first region impurity concentration of the first conductive type; and
a second region, surrounded by the second portion of the doped region and the second region of the semiconductor layer having a second region impurity concentration of the first conductive type, wherein the second region impurity concentration of the second region is lower than the first region impurity concentration of the first region.

5. The pixel structure according to claim 4, wherein the first portion of the doped region has a first impurity concentration of the second conductive type, the second portion of the doped region has a second impurity concentration of the second conductive type, and the first impurity concentration of the first portion is smaller than the second impurity concentration of the second portion.

6. The pixel structure according to claim 4, wherein the second portion of the doped region is in direct contact with the first portion of the doped region, and the second region of the semiconductor layer is in direct contact with the first region of the semiconductor layer.

7. The pixel structure according to claim 4, wherein the doped region further comprises:
at least one third portion between the first portion of the doped region and the second portion of the doped region, the at least one third portion of the doped region has a third width in the second direction and the third width between the first width and the second width.

8. The pixel structure according to claim 7, wherein the first portion of the doped region has a first impurity concentration of the second conductive type, the second portion of the doped region has a second impurity concentration of the second conductive type, the third portion of the doped region has a third impurity concentration of the second conductive type, and each of the first impurity concentration, the second impurity concentration and the third impurity concentration is larger than an impurity concentration of the semiconductor layer.

9. The pixel structure according to claim 8, wherein the first impurity concentration of the first portion is smaller than the second impurity concentration of the second portion, and the third impurity concentration of the third portion is between the first impurity concentration of the first portion and the second impurity concentration of the second portion.

10. The pixel structure according to claim 7, wherein the semiconductor layer further comprises:
at least one third region between the first region of the semiconductor layer and the second region of the semiconductor layer, the at least one third region of the semiconductor layer has a third width in the second direction and the third width being between the first width of the first region of the semiconductor layer and the second width of the second region of the semiconductor layer.

11. The pixel structure according to claim 1, wherein the doped region has a width turning point at a first depth in the semiconductor layer.

12. The pixel structure according to claim 1, wherein the semiconductor layer has a step boundary interfacing the doped region.

13. The pixel structure according to claim 1, wherein surfaces of the doped region, the trench isolation and the semiconductor layer are substantially coplanar.

14. The pixel structure according to claim 1, wherein the doped region is in direct contact with the trench isolation and the semiconductor layer.

15. The pixel structure according to claim 1, further comprising:
a transfer gate disposed on the first surface; and
a floating diffusion region disposed in the semiconductor substrate and adjacent to the first surface, wherein the transfer gate is configured to selectively couple the photodiode to the floating diffusion region.

16. The pixel structure according to claim 1, wherein the doped region has a vertical thickness being the same as a trench depth of the trench isolation with respect to the first surface.

17. A method of forming a pixel structure, comprising:
forming a trench and a semiconductor layer of a first conductive type in a semiconductor substrate, wherein the semiconductor layer is surrounded by the trench;
forming a doped region in the semiconductor layer adjacent to the trench, wherein the doped region is of a second conductive type opposite to the first conductive type and arranged to extend from a first depth to the second surface;
diffusing first impurities of the second conductive type into the semiconductor layer between the trench and the first surface to form a first doped portion of the doped region between the first surface and the first depth and a second doped portion between the first depth and the second surface; and
forming a trench isolation in the trench.

18. The method according to claim 17, wherein forming the doped region in the semiconductor layer comprises:
forming a stopper layer lining only a first trench portion of the trench between the first surface and the first depth while a second trench portion of the trench between the first depth and the second surface is free of the stopper layer; and
diffusing second impurities of the second conductive type into the semiconductor layer through the second trench portion of the trench.

19. The method according to claim 18, wherein diffusing the second impurities of the second conductive type into the semiconductor layer comprises:
forming the second impurities of the second conductive type through the second trench portion of the trench by a plasma doping process; and
diffusing the second impurities of the second conductive type into the semiconductor layer by an annealing process.

20. The pixel formation method according to claim 18, wherein diffusing the second impurities of the second conductive type into the semiconductor layer comprises:
depositing a layer including the second impurities of the second conductive type adjacent to the first trench portion and the second trench portion of the trench; and
diffusing the second impurities of the second conductive type into the semiconductor layer by an annealing process.
